(19) United States
(12) Patent Application Publication
(10) Pub. No.: US 2009/0103382 A1
(43) Pub. Date: Apr. 23, 2009

(54) Gated Diode Sense Amplifiers

(76) Inventors: Wing Kin Luk, Chappaqua, NY (US); Robert Heath Dennard, Croton-on-Hudson, NY (US)

Correspondence Address: RYAN, MASON & LEWIS, LLP, 90 FOREST AVENUE, LOCUST VALLEY, NY, 11560, US

(21) Appl. No.: 11/874,220

(22) Filed: Oct. 18, 2007

(51) Int. Cl. G11C 7/00; H01R 43/00

(52) U.S. Cl. 365/205; 29/825; 327/51

(57) ABSTRACT

A sense amplifier for use in sensing a signal in an integrated circuit comprises an amplifier portion and an output portion. The amplifier portion comprises a gated diode having a gate terminal. The output portion comprises an output transistor in signal communication with the gate terminal of the gated diode and having a source terminal. A variable source voltage acts on the source terminal of the output transistor when the sense amplifier is in operation. The variable source voltage is temporarily altered when the sense amplifier is actively sensing the signal in the integrated circuit.

### CROSS REFERENCE TO RELATED APPLICATIONS

This application is related to an application by Luk et al., entitled “Amplifiers Using Gated Diodes,” U.S. Patent Application Publication No. 2005/0145895 A1, having common inventors herewith, commonly assigned herewith, and incorporated by reference herein.

### FIELD OF THE INVENTION

The present invention is directed generally to integrated circuits, and, more particularly, to sense amplifiers for use in integrated circuits.

### BACKGROUND

A gated diode is a two terminal semiconductor device. It may, for example, comprise a field effect transistor (FET) with an open drain terminal or a FET with source and drain terminals shorted together. Such a device is typically characterized by an effective capacitance that depends on the difference between the voltages on the gate and source terminals, Vgs, relative to a threshold voltage. An n-type gated diode typically has a large effective capacitance when Vgs is above the threshold voltage and has a very small effective capacitance when Vgs is below the threshold voltage.

Sense amplifiers may be used in any integrated circuit applications that require the detection of small signals such as data memories, data communications, small signal data transmissions, small signal instrumentation, and low power data buses. A sense amplifier in an integrated circuit memory, for example, is a support circuit that is adapted to determine the state of a selected memory cell based on a signal received from that memory cell and to output a full logic level corresponding to this signal. The unique properties of gated diodes make them attractive for use in sense amplifiers in integrated circuit memories (e.g., dynamic random access memories (DRAMs) or static random access memories (SRAMs)). In several designs, for example, the use of a gated diode in a sense amplifier will result in a sense amplifier that is faster than one without a gated diode, as well as in reduced silicon area usage and power consumption. Nevertheless, even though gated diode sense amplifiers frequently display performance characteristics better than non-gated-diode sense amplifiers, there is still a need for further refinements to gated diode sense amplifier designs which allow these designs to achieve even better performance characteristics.

### SUMMARY OF THE INVENTION

Embodiments of the present invention address the above-identified need by providing gated diode sense amplifiers comprising transistors having source voltages that vary with sense amplifier operating phase.

In accordance with an aspect of the invention, a sense amplifier for use in sensing a signal in an integrated circuit comprises an amplifier portion and an output portion. The amplifier portion comprises a gated diode having a gate terminal. The output portion comprises an output transistor in signal communication with the gate terminal of the gated diode and having a source terminal. A variable source voltage acts on the source terminal of the output transistor when the sense amplifier is in operation. The variable source voltage is temporarily altered when the sense amplifier is actively sensing the signal in the integrated circuit.

In accordance with one of the above-identified embodiments of the invention, a sense amplifier for use in an integrated circuit memory comprises an isolation transistor, a gated diode, and an inverter. A variable source voltage is applied to a source terminal of an n-type field effect transistor (NFET) in the inverter using a specialized enhancement circuit. This enhancement circuit holds the source voltage high when the sense amplifier is not actively sensing the logic state of a memory cell, and temporarily reduces the source voltage when the sense amplifier is actively sensing the logic state of a memory cell. Keeping the source voltage high when not actively sensing reduces the standby leakage current of the sense amplifier. Reducing the source voltage when actively sensing increases the gate overdrive of the NFET in the inverter and, thereby, increases the operating speed of the sense amplifier.

These and other features and advantages of the present invention will become apparent from the following detailed description which is to be read in conjunction with the accompanying drawings.

### BRIEF DESCRIPTION OF THE DRAWINGS

FIG. 1 shows a schematic diagram of a first gated diode sense amplifier.

FIG. 2 shows a signal timing diagram of a method of operating the FIG. 1 gated diode sense amplifier.

FIG. 3 shows a schematic diagram of a second gated diode sense amplifier.

FIG. 4 shows a schematic diagram of a third gated diode sense amplifier.

FIG. 5 shows a schematic diagram of a gated diode sense amplifier in accordance with a first illustrative embodiment of the invention.

FIGS. 6A and 6B show signal timing diagrams for reading a signal-1 and signal-0, respectively, using the FIG. 5 gated diode sense amplifier.

FIG. 7 shows a schematic diagram of a gated diode sense amplifier in accordance with a second illustrative embodiment of the invention.

FIG. 8 shows a schematic diagram of a gated diode sense amplifier in accordance with a third illustrative embodiment of the invention.

FIG. 9 shows the FIG. 5 gated diode sense amplifier with an enhancement circuit.

FIG. 10 shows the FIG. 7 gated diode sense amplifier with an enhancement circuit.

FIG. 11 shows the FIG. 8 gated diode sense amplifier with an enhancement circuit.

FIG. 12 shows a schematic diagram of gated diode sense amplifiers in accordance with aspects of the invention incorporated into a data memory.

FIG. 13 shows a schematic diagram of gated diode sense amplifiers in accordance with aspects of the invention incorporated into a low power data bus.

FIG. 14 shows a schematic diagram of a gated diode sense amplifier in accordance with aspects of the invention incorporated into a small signal instrument.

### DETAILED DESCRIPTION OF THE INVENTION

The present invention will be described with reference to illustrative embodiments. For this reason, numerous modifications can be made to these embodiments and the results will still come within the scope of the invention. No limitations with respect to the specific embodiments described herein are intended or should be inferred.

Although embodiments of this invention described herein are directed to sense amplifiers in integrated circuit memories, the invention is not limited to this particular application. Rather, aspects of the invention may utilized in any integrated circuit applications that require the detection of small signals such as, but not limited to, data memories, data communications, small signal data transmissions, small signal instrumentation, and low power data buses.

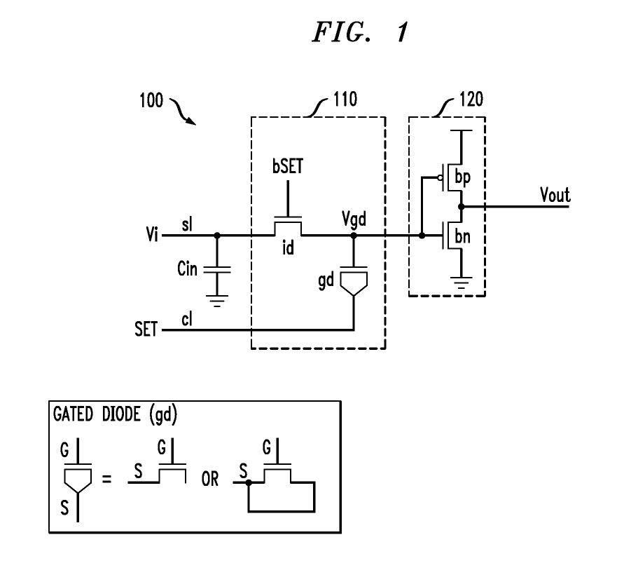

FIG. 1 shows a sense amplifier 100 for use in sensing a logic state of a memory cell in an integrated circuit memory. The sense amplifier comprises an amplifier portion 110 that is coupled to an output portion 120. The amplifier portion comprises a gated diode gd and an isolation device id. A control line cl is coupled to the source terminal of the gated diode. The output portion comprises an output n-type field effect transistor (NFET) bn and an output p-type field effect transistor (PFET) bp configured as an inverter.

When sensing the logic state of a selected memory cell, the sense amplifier 100 receives a signal, Vi, from the memory cell on a signal line sl (e.g., a bitline). Because the signal line may access a multiplicity of memory cells, the signal line may have a relatively high capacitance, Cin, and the signal developed on the signal line Vi may be quite small. For a logic one, for example, Vi may only have a magnitude of about 10-20 percent of the supply voltage (VDD) for the integrated circuit memory, while, for a logic zero, Vi may be 0 V (GND). This signal, in turn, passes through the amplifying portion 110 of the sense amplifier to the output portion 120 (i.e., the inverter). In response to this signal, the inverter produces a full logic level output, Vout, which is complementary to the voltage on the gate terminal of the gated diode, Vgd. In this way, the sense amplifier produces a full logic level output signal corresponding to the logic state of a sensed memory cell.

The signal line sl is connected to the gated diode gd by the isolation device id. In the particular sense amplifier 100, the isolation device comprises an NFET. During the (signal) sampling phase, the isolation device is on and the signal Vi appears at the gate of the gated diode Vgd. A control signal SET, which is normally ground during the sampling phase and is raised to positive during the (signal) sensing phase, is applied to the source of the gated diode to operate the gated diode. The isolation device is adapted to be turned on when Vgd is below a predetermined value and to be turned off “unidirectionally” when Vgd rises above this predetermined value during signal amplification of the sensing phase. These operating characteristics may be accomplished by placing a substantially constant voltage or a pulse complementary to the SET signal, bSET, on the gate terminal of the isolation device that is greater than a threshold voltage of the isolation device, Vt_id, by about the expected magnitude of Vi for a logic one. The high voltage of bSET may, for example, be set such that:

bSET=Vi_max+Vt_id+V_margin,

where Vi_max is the expected magnitude of Vi for a logic one, and V_margin is an optional small voltage for design margin. This allows the isolation device to decouple the gate terminal of the gated diode from the signal line so that the voltage gained from the gated diode is not affected by Cin, and so that Vgd does not propagate into the signal line sl and disturb Vi.

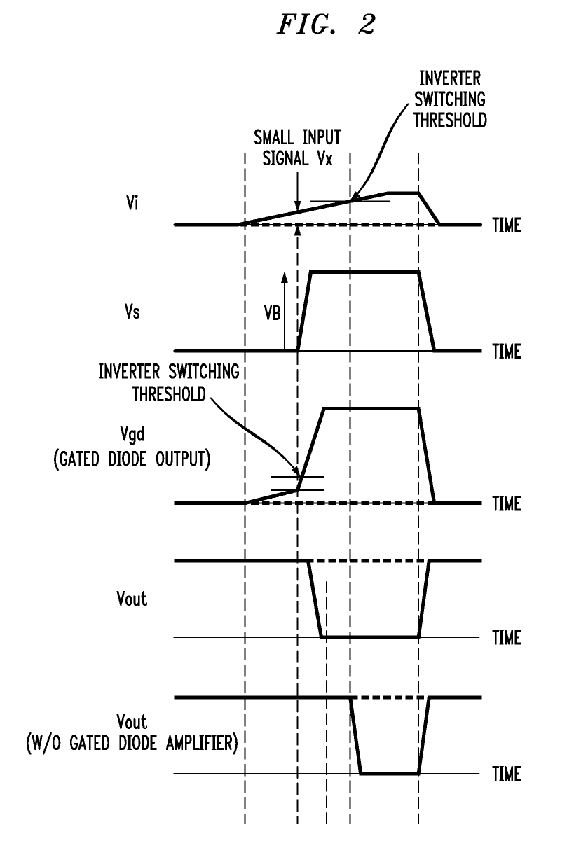

In FIG. 2, the voltage of the various signals of the sense amplifier 100 are plotted versus time to illustrate a method of operation. During the sampling phase, the isolation device is on. After Vi is allowed to develop for a predetermined amount of time, SET, applied to the control line cl, is raised to high in order boost the source terminal voltage of the gated diode by an amount VB. If Vi is a logic zero, Vgd stays almost at 0 V (GND) since the gated diode has almost no capacitance under these conditions. If, however, Vi is a logic one, the gated diode is on and charge is stored in its inversion layer, causing Vgd to rapidly rise. This rapid rise occurs almost immediately after SET is boosted because the capacitive load on the gate of the gated diode is small since it is decoupled from Cin by the isolation device id, as id is turned off during the sensing phase. This fast voltage rise, in turn, activates the output portion 110, causing the output portion to output Vout. Advantageously, the voltage drop in Vout in the sense amplifier 100 may occur substantially earlier in time than it would in a sense amplifier without a gated diode. The gated sense amplifier 100 may thereby display faster operating characteristics than conventional sense amplifier designs. As compared to other sense amplifiers for small signals, e.g. the common cross-coupled sense amplifier, the gated diode sense amplifier uses a fewer number of transistors and hence requires smaller silicon areas and less power.

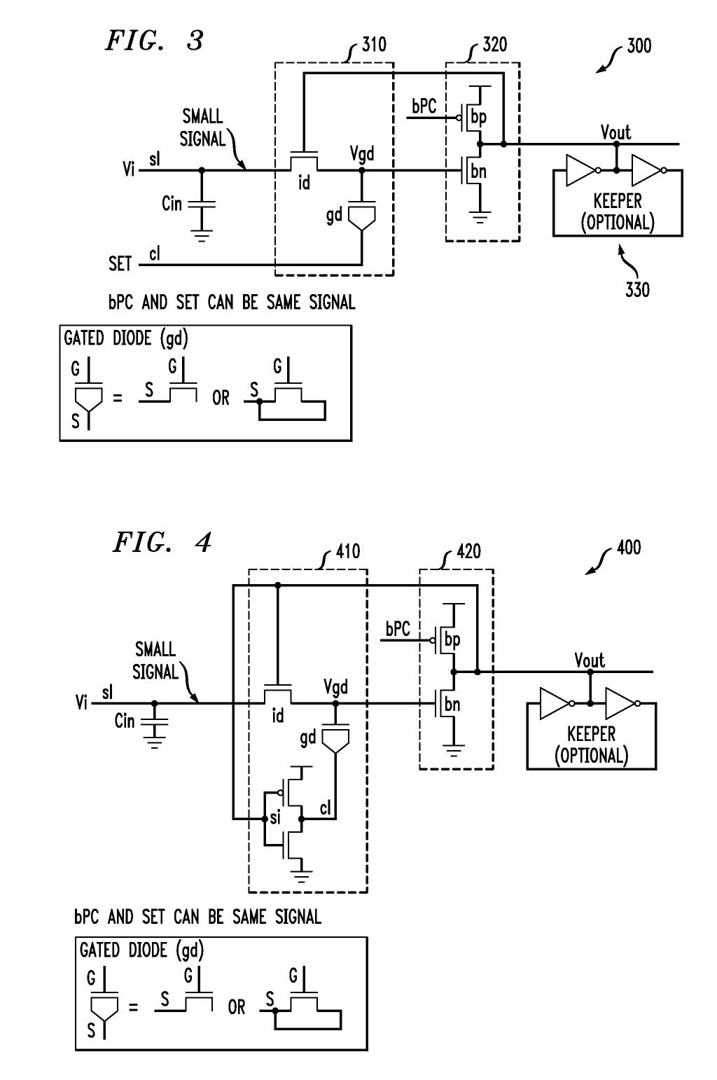

There may be several variations on the sense amplifier 100 shown in FIG. 1. FIG. 3, for example, shows a sense amplifier 300 with an amplifier portion 310 and output portion 320 configured such that Vout is applied to the gate terminal of the isolation device id and a separate gate voltage, bPC, is applied to the output PFET bp for precharging the node Vout to a predetermined state during the sample phase. The voltage bPC is preferably equal to SET. This configuration allows the isolation device to be controlled by Vout rather than by a separate voltage input (e.g., bSET or a constant voltage as described earlier). For example, when sensing a logic one, Vi will be transmitted through the isolation device to the gate of the gated diode gd, where it will cause the gated diode to start to store charge and Vgd to rise. As soon as Vgd rises above the threshold voltage of the output NFET bn, the inverter in the output portion outputs a low Vout (e.g., GND). This low signal will turn off the isolation device, thereby isolating the amplifier portion and the output portion of the sense amplifier from the signal line sl and Vi. Thus, the use of Vout to control the isolation device eliminates the need for a separate bSET signal for the isolation device.

As indicated in FIG. 3, the sense amplifier 300 may also comprises an optional keeper circuit 330. The keeper circuit acts to hold the sensed voltage stable at dynamic node Vout which otherwise may get corrupted due to leakage through the PFET pn and the NFET bn, or any switching noise coupling to the node Vout.

FIG. 4, moreover, shows a gated diode sense amplifier 400 comprising an amplifier portion 410 and an output portion 420. This sense amplifier is similar to the sense amplifier 300 in FIG. 3, but, in the sense amplifier 400, Vout is further routed to a SET inverter si. Upon receiving Vout from the output portion, the SET inverter acts to invert Vout and to send the resultant signal to the source terminal of the gated diode gd. Thus, Vout drives a signal applied to the source terminal of the gated diode. This configuration eliminates the need for a separate SET signal for the gated diode. As soon as the sense amplifier begins to react to Vi, the source terminal of the gated diode is set high. This self-setting of the sense amplifier reduces the timing uncertainty related to the precision and margin needed to set the sense amplifier by raising the source voltage of the gated diode.

It will be observed that, in the sense amplifiers 100, 300, and 400 shown in FIGS. 1, 3 and 4, respectively, no provision is made for dynamically changing the voltages on the source terminals (source voltages, Vs) of the output NFETs bn of the output portions 120, 320, and 420, respectively. In other words, in each case, Vs is held at a constant voltage, GND (e.g., 0 V). Nevertheless, a constant Vs may not be ideal. Instead, performance advantages may be obtained by temporarily (i.e., dynamically) altering Vs as a function of the operating phase of the sense amplifier. When the sense amplifier is actively sensing the logic state of a memory cell (i.e., the sense amplifier is in a sensing phase), temporarily lowering Vs (e.g., to GND) results in a larger gate overdrive on the output NFET, which, in turn, may lead to a faster output speed for the inverter constituting the output portion. In contrast, when the sense amplifier is not actively sensing the logic state of a selected memory cell (i.e., the sense amplifier is in a sampling phase), it may be beneficial to set Vs back to a bias voltage, Vbias, that is higher than GND in order to fully switch off the output NFET and thereby reduce standby leakage current. Reducing standby leakage currents in this manner saves power and reduces the parasitic effects of the sense amplifier on any devices that may be connected to the sense amplifier.

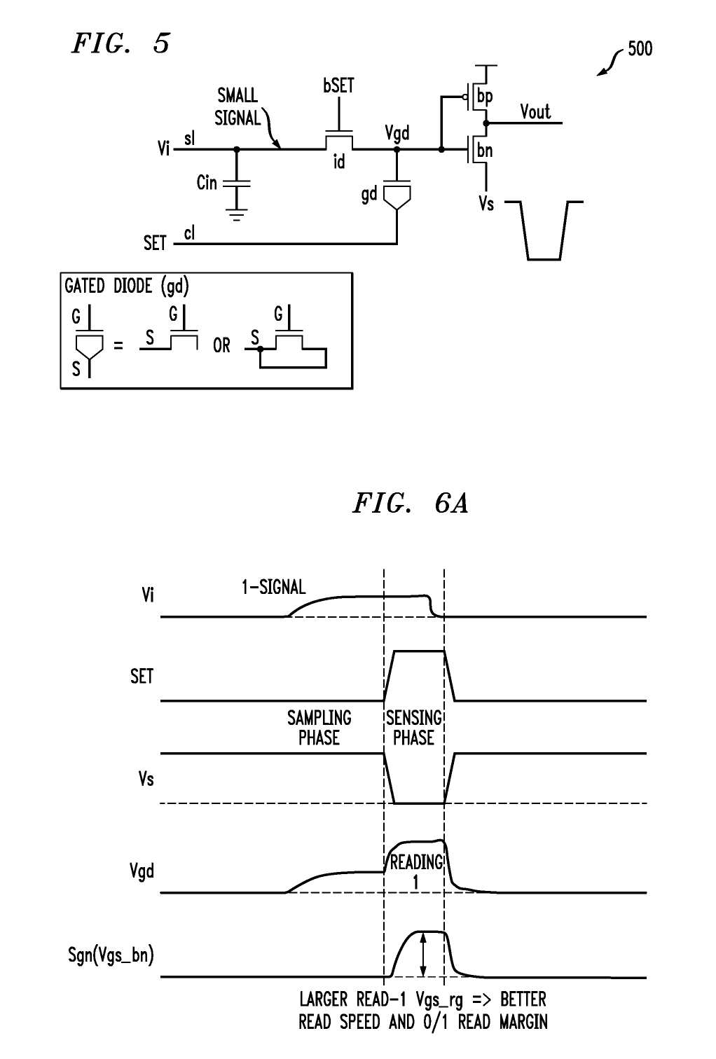

FIG. 5 shows a sense amplifier 500 in accordance with a first illustrative embodiment of the invention. The sense amplifier has a design similar to the sense amplifier 100 shown in FIG. 1 and also functions in a similar manner. However, in the sense amplifier 500, Vs is dynamically altered as a function of the operating phase of the sense amplifier. More specifically, Vs is temporarily reduced from Vbias to GND when the sense amplifier is in its sense phase in order to achieve the above-described benefits. When in the sample phase, Vs remains at Vbias. Vbias may, for example, be VDD.

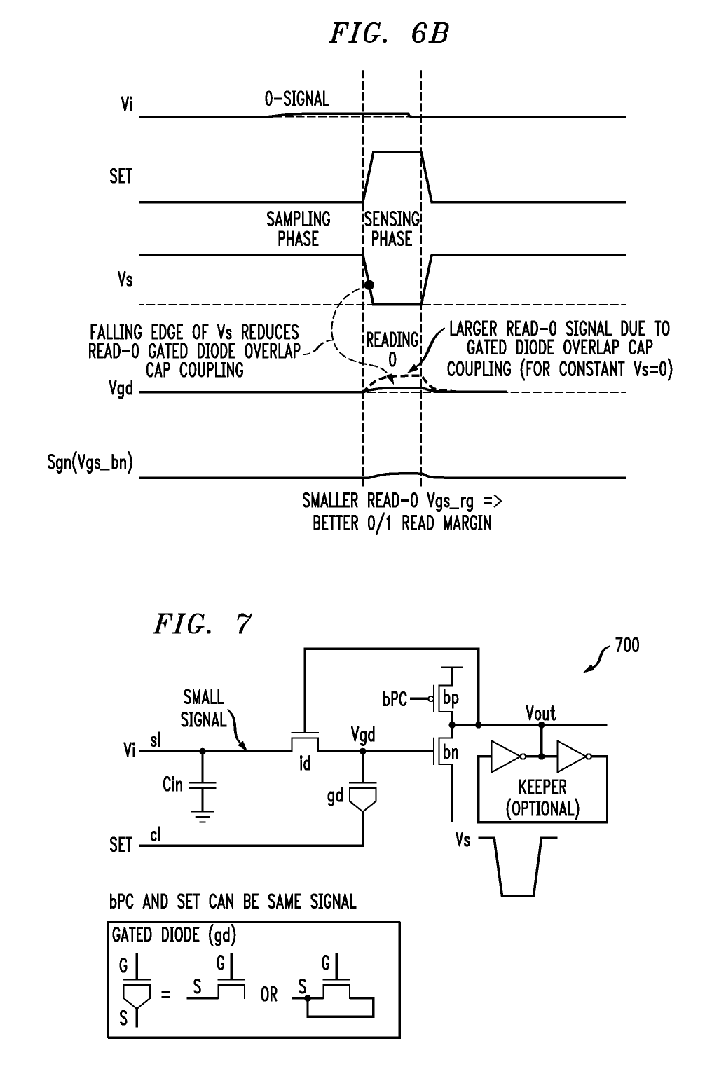

Notably, the dynamic altering of the source voltage Vs also acts to improve the read-margin between reading a signal-1 and reading a signal-0, thereby enhancing the difference between the two voltage levels at the input (Vgd) of the output inverter. Such an effect is best illustrated by the signal timing diagrams for the sense amplifier 500 shown in FIGS. 6A and 6B, which show Vi, SET, Vs, Vgd and Sgn(Vgs_bn) for reading a signal-1 and a signal-0, respectively. Sgn(Vgs_nb) is the positive portion of the gate to source voltage of the transistor bn of the output inverter, which is the difference between Vgd and Vs.

Reference to FIG. 6A shows that, at the start of the sensing phase when reading a signal-1, the SET signal applied to the source of the gated diode gd is pulsed high and Vs is dropped to GND. The voltage Vgd is boosted higher, amplifying the original signal Vi by means of the capacitive coupling of the gated diode. Sgn(Vgs_bn) determines the gate overdrive acting on the transistor bn. With Vs being temporarily at GND during the sensing phase, the gate overdrive for the transistor bn for reading a signal-1, Vgs_bn_od(1), is:

Vgs_bn_od(1)=Vgd_boost(1)−Vt_bn,

where Vgd_boost(1) is the boosted voltage at Vgd when reading a signal-1, and Vt_bn is the threshold voltage of the output transistor bn. It is about the same when Vs is held constant at GND.

In contrast, FIG. 6B shows a signal timing diagram similar to FIG. 4B, but in this case, for reading a signal-0. In this case, Vi is practically 0. At the beginning of the sensing phase, the SET signal is raised to high. Ideally, Vgd is left low as the gated diode gd does not store any substantial charge. Vs is again temporarily dropped to GND, and Vgd does not substantially rise and the output transistor bn is not turned on. This, of course, can be readily distinguished compared to the case of reading a signal-1. Nevertheless, as technology is scaled down to transistor feature sizes below about 100 nanometers, the capacitive coupling between the gate and the source of the gated diode may not be neglected even for Vgs<Vgd_th. Such capacitance is usually characterized as the overlap capacitance Cgd_ov. As a result of Cgd_ov, the voltage Vgd is not completely zero during the sensing phrase even when the input signal Vi is practically zero, since the rising SET signal is coupled through the overlap capacitance to the node Vgd. As a result, even though Vgd is much smaller when reading a signal-0 than when reading a signal-1, the capacitive coupling may adversely reduce the signal difference (or signal margin) between a signal-1 and a signal-0 at the gate of the output transistor bn.

Advantageously, however, reducing Vs during a read operation helps to mitigate this unfavorable effect. As Vs is pulled down while reading a signal-0, the gate to source capacitance of the transistor bn, Cgs_bn, produces a coupling effect that pulls down the gate voltage of the transistor bn. Simultaneously, the gated diode's overlap capacitance between gate and the source, Cgd_ov, produces a coupling effect that acts to pull up the gate voltage of the transistor bn. These two coupling effects appear to cancel each other since the two capacitances are about the same and the two pulses for Vs and SET are of about the same order of magnitude. The cancellation of the two effects results in a smaller Vgd at the gate of the output transistor bn than that which would be present if Vs had been left at GND while actively sensing. As a result, the read margin, defined as the difference between Vgd(1) and Vgd(0), is increased by dynamically altering Vs in accordance with aspects of the invention.

FIGS. 7 and 8 show sense amplifiers 700 and 800 in accordance with second and third illustrative embodiments of the invention, respectively. The sense amplifier 700 has a design and functions in a manner similar to the sense amplifier 300 in FIG. 3, while the sense amplifier 800 has a design and functions in manner similar to the sense amplifier 400 in FIG. 4. However, like the sense amplifier 500 in FIG. 5, the sense amplifiers 700, 800 also implement a dynamically varying Vs.

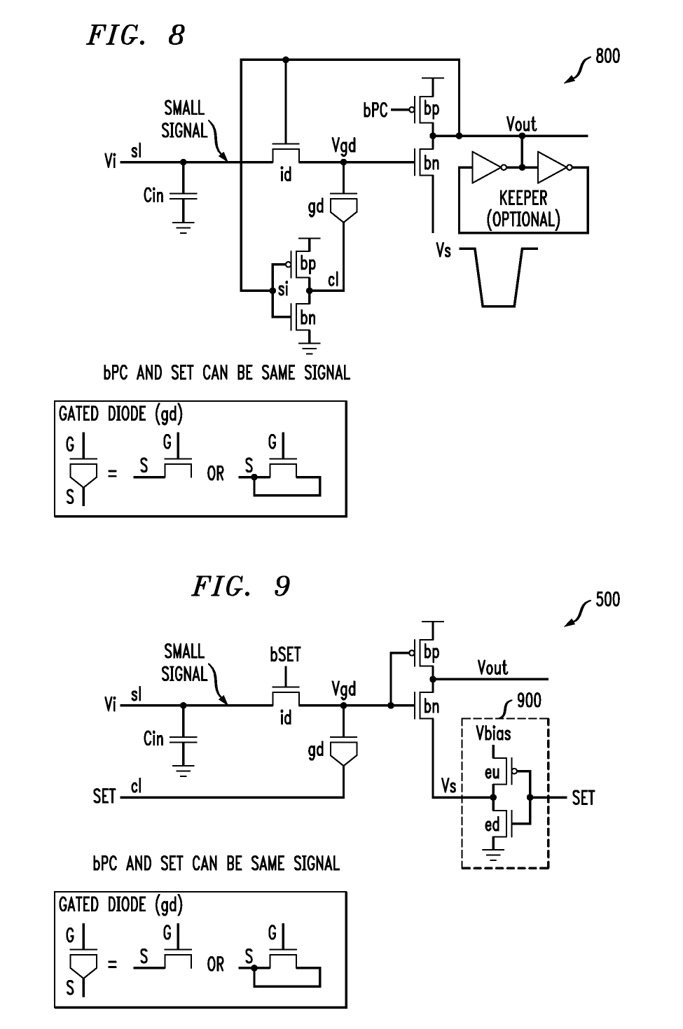

FIG. 9 shows the FIG. 5 sense amplifier 500 with the addition of an illustrative enhancement circuit 900 that is adapted to vary Vs as a function of the operating phase of the sense amplifier. The enhancement circuit comprises a pullup transistor eu and a pulldown transistor ed and essentially acts as an inverter for the SET signal. As described earlier with respect to FIG. 2, SET is pulsed high as part of a sensing sequence. When SET is high, the enhancement circuit temporarily sets Vs to GND for the duration of the SET pulse. In contrast, when SET returns to low (e.g., GND), Vs is set to Vbias (e.g., VDD). The enhancement circuit thereby accomplishes the dynamic Vs modulation described above.

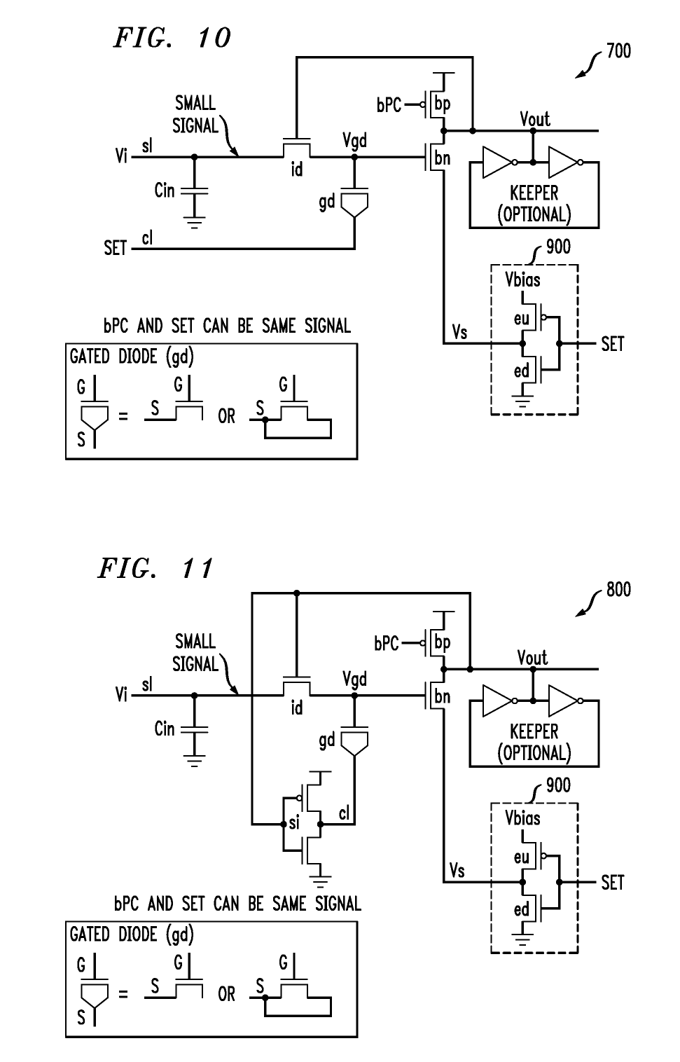

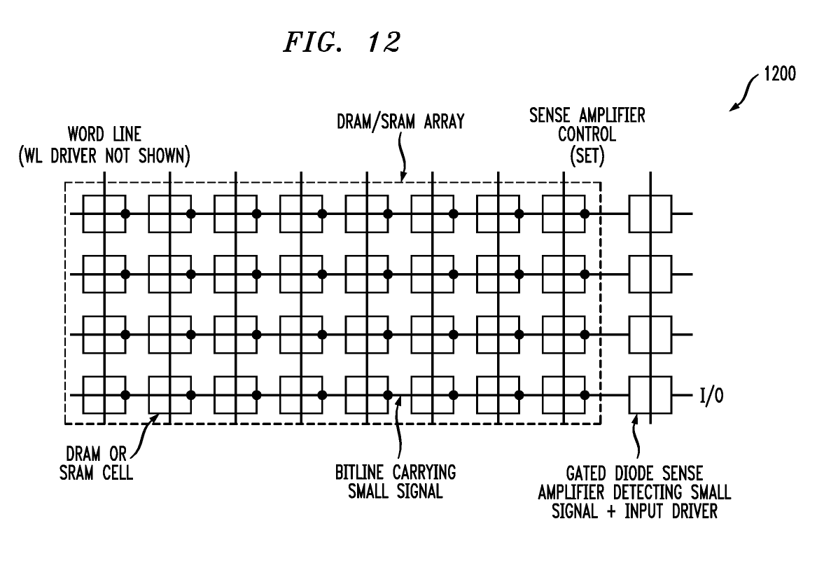

Likewise, FIGS. 10 and 11 show the enhancement circuit 900 applied to the sense amplifier 700 and the sense amplifier 800, respectively.

It is noted that the sense amplifiers described herein use n-type transistors for the isolation devices id and the gated diodes gd. Nevertheless, for the case of p-type transistors or mixed n- and p-type transistors, the approach can be extended accordingly. Where p-type transistors are utilized, voltages will be implemented in the corresponding complementary form, as will be understood by one skilled in the art.

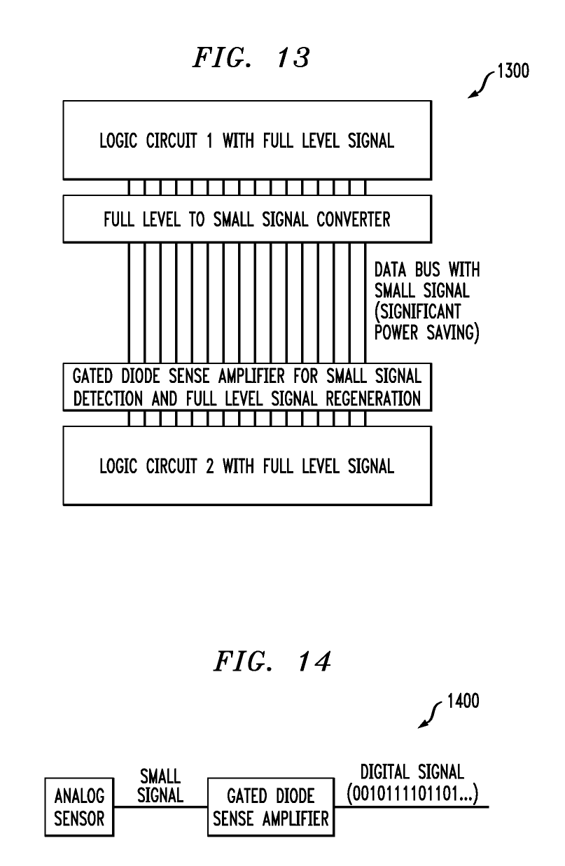

FIGS. 12-14 show schematic diagrams of gated diode sense amplifiers in accordance with aspects of this invention in various illustrative applications. More specifically, FIG. 12 shows an illustrative data memory 1200 (dynamic random access memory (DRAM) or static random access memory (SRAM)), FIG. 13 shows an illustrative low power data bus 1300, and FIG. 14 shows an illustrative small signal instrument 1400.

The sense amplifier designs described above are part of the design for an integrated circuit chip. The chip design is created in a graphical computer programming language, and is stored in a computer storage medium (such as a disk, tape, physical hard drive or virtual hard drive such as in a storage access network). If the designer does not fabricate chips or photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are formed on a wafer. The photolithographic masks are utilized to define areas of the wafer (and/or the layers thereon) to be etched or otherwise processed.

The resulting integrated circuit chips may be distributed by the fabricator in raw wafer form (i.e., as a single wafer that has multiple unpackaged chips), as a bare die, or in packaged form. In the latter case, the chip is mounted in a single chip package (e.g., plastic carrier with leads that are affixed to a motherboard or other higher level carrier) or in a multichip package (e.g., ceramic carrier that has either or both surface interconnections or buried interconnections). In any case, the chip is then integrated with other chips, discrete circuit elements, and/or other signal processing devices as part of either an intermediate product (e.g., motherboard) or an end product. The end product may be any product that includes integrated circuit chips, ranging from toys and other low-end applications to advanced computer products having a display, a keyboard or other input device, and a central processor.

Although illustrative embodiments of the present invention have been described herein with reference to the accompanying figures, it is to be understood that the invention is not limited to those precise embodiments, and that various other changes and modifications may be made to these embodiments by one skilled in the art without departing from the scope of the appended claims.

What is claimed is:

1. A sense amplifier for sensing a signal in an integrated circuit, the sense amplifier comprising:
an amplifier portion, the amplifier portion comprising a gated diode having a gate terminal; and
an output portion, the output portion comprising an output transistor in signal communication with the gate terminal of the gated diode and having a source terminal;
wherein a variable source voltage acts on the source terminal of the output transistor when the sense amplifier is in operation, the variable source voltage being temporarily altered when the sense amplifier is actively sensing the signal in the integrated circuit.

2. The sense amplifier of claim 1, wherein the integrated circuit comprises a dynamic random access memory.

3. The sense amplifier of claim 1, wherein the integrated circuit comprises a static random access memory.

4. The sense amplifier of claim 1, wherein the gated diode comprises a transistor with a drain terminal that is electrically open.

5. The sense amplifier of claim 1, wherein the gated diode comprises a transistor with a source terminal shorted to a drain terminal.

6. The sense amplifier of claim 1, wherein the output transistor is implemented in an inverter.

7. The sense amplifier of claim 1, wherein the output portion is adapted to produce an output signal corresponding to a voltage at the gate terminal of the gated diode.

8. The sense amplifier of claim 7, wherein the output signal drives a signal applied to a source terminal of the gated diode.

9. The sense amplifier of claim 1, wherein the output transistor is n-type and the variable source voltage is adapted to be temporarily reduced when the sense amplifier is actively sensing the signal in the integrated circuit.

10. The sense amplifier of claim 1, wherein the output transistor is p-type and the variable source voltage is adapted to be temporarily increased when the sense amplifier is actively sensing the signal in the integrated circuit.

11. The sense amplifier of claim 1, wherein the sense amplifier further comprises an isolation transistor, the isolation transistor comprising a source or drain terminal in signal communication with the gate terminal of the gated diode.

12. The sense amplifier of claim 11, wherein the isolation transistor further comprises a gate terminal on which is applied a substantially constant voltage when the sense amplifier is in operation.

13. The sense amplifier of claim 11, wherein the isolation transistor further comprises a gate terminal on which is applied a signal produced by the output portion when the sense amplifier is in operation.

14. The sense amplifier of claim 11, wherein the isolation transistor is adapted to be turned off when a voltage on the gate terminal of the gated diode is greater than a predetermined voltage, and to be turned on when the voltage on the gate terminal of the gated diode is less than a predetermined voltage.

15. The sense amplifier of claim 1, wherein the variable source voltage acts to modify the speed of the sense amplifier.

16. An integrated circuit comprising a sense amplifier for use in sensing a signal in the integrated circuit, the sense amplifier comprising:
an amplifier portion, the amplifier portion comprising a gated diode having a gate terminal; and
an output portion, the output portion comprising an output transistor in signal communication with the gate terminal of the gated diode and having a source terminal;
wherein a variable source voltage acts on the source terminal of the output transistor when the sense amplifier is in operation, the variable source voltage being temporarily altered when the sense amplifier is actively sensing the signal in the integrated circuit.

17. The integrated circuit of claim 16, further comprising an enhancement circuit operative to temporarily alter the variable source voltage acting on the source terminal of the output transistor when the sense amplifier is actively sensing the signal in the integrated circuit

18. The integrated circuit of claim 17, wherein the enhancement circuit comprises at least one of a pullup transistor and a pulldown transistor.

19. The integrated circuit of claim 17, wherein the enhancement circuit comprises an inverter.

20. A method of forming a sense amplifier for use in sensing a signal in an integrated circuit, the method comprising the steps of:
forming an amplifier portion, the amplifier portion comprising a gated diode having a gate terminal; and
forming an output portion, the output portion comprising an output transistor in signal communication with the gate terminal of the gated diode and having a source terminal;
wherein a variable source voltage acts on the source terminal of the output transistor when the sense amplifier is in operation, the variable source voltage being temporarily altered when the sense amplifier is actively sensing the signal in the integrated circuit.
